(19) United States
(12) Patent Application Publication
(10) Pub. No.: US 2020/0321413 A1
(43) Pub. Date: Oct. 8, 2020

(54) RESONANT CAVITY STRUCTURE OF PIXEL OF OLED DISPLAY PANEL AND OLED DISPLAY PANEL

(71) Applicant: SHENZHEN ROYOLE TECHNOLOGIES CO., LTD., Shenzhen (CN)

(72) Inventor: Dingyang HONG, Shenzhen (CN)

(21) Appl. No.: 16/905,187

(22) Filed: Jun. 18, 2020

Related U.S. Application Data
(63) Continuation of application No. PCT/CN2017/117333, filed on Dec. 20, 2017.

(51) Int. Cl. H01L 27/32; H01L 51/52

(52) U.S. Cl. CPC H01L 27/3246; H01L 51/5265; H01L 51/5271; H01L 2251/308; H01L 51/5206; H01L 51/5221; H01L 27/3262

(57) ABSTRACT

A resonant cavity structure (10) of a pixel (100) of an OLED display panel (1000) is provided. The resonant cavity structure (10) includes a PDL (12), a resonant cavity (14), and a reflective film (16). The PDL (12) defines a groove (122) and includes a side surface (1222) of the groove. The resonant cavity (14) is defined in the groove (122). The reflective film (16) is arranged in the groove (122) and covers the side surface (1222) of the groove.

### CROSS-REFERENCE TO RELATED APPLICATION(S)

This application is a continuation of International Patent Application No. PCT/CN2017/117333, filed on Dec. 20, 2017, the entire disclosure of which is hereby incorporated by reference in their entireties.

### TECHNICAL FIELD

This disclosure relates to the technical field of display devices, and more particularly to a resonant cavity structure of a pixel of an organic light emitting diode (OLED) display panel and an OLED display panel.

### BACKGROUND

In a resonant cavity structure of a pixel of an OLED display panel in the related art, a resonant cavity is defined in a groove defined in a pixel define layer (PDL). During working, some light rays in the resonant cavity may be directed to the PDL and absorbed by PDL material or refracted out of the resonant cavity by the PDL material, and thus cannot be finally emitted, which results in reduction in light extraction efficiency of pixels of the OLED display panel.

### SUMMARY

To this end, implementations provide a resonant cavity structure of a pixel of an OLED display panel.

The resonant cavity structure provided herein is applicable to a pixel of an OLED display panel. The resonant cavity structure includes a PDL, a resonant cavity, and a reflective film. The PDL defines a groove and includes a side surface of the groove. The resonant cavity is defined in the groove. The reflective film is arranged in the groove and covers the side surface of the groove.

The OLED display panel provided herein includes a thin-film transistor (TFT) substrate and multiple pixels arranged in array on the TFT substrate, where each of the multiple of pixels includes the resonant cavity structure described above.

Additional aspects and advantages of implementations of the present disclosure will be partially given in the following description, and some will become apparent from the following description or be learned through practice of the present disclosure.

### BRIEF DESCRIPTION OF THE DRAWINGS

The above and/or additional aspects and advantages of implementations of the present disclosure will become apparent and easily understood from description of implementations in conjunction with the following accompanying drawings

FIG. 1 is a schematic sectional view of an OLED display panel according to implementations.

FIG. 2 is a schematic plan view of an OLED display panel according to implementations.

FIG. 3 is a schematic diagram illustrating working principles of a resonant cavity structure in the related art.

FIG. 4 is a schematic diagram illustrating working principles of a resonant cavity structure according to implementations.

FIG. 5 is a schematic diagram illustrating laminate order and thickness of reflective film materials according to implementations.

FIG. 6 is an emergent light spectrum diagram of reflective film materials in cooperation with a resonant cavity structure according to implementations.

Brief description of symbols of major components: OLED display panel 1000, pixel 100, resonant cavity structure 10, anode layer 11, top surface 112 of anode layer, PDL 12, groove 122, side surface 1222 of groove, top surface 124 of PDL, reflective film 16, hole layer 13, cavity portion 132, extension portion 134, light-emitting layer 15, electron layer 17, cathode layer 18, resonant cavity 14, TFT substrate 200, light extraction layer 300.

### DETAILED DESCRIPTION

The following provides various different implementations or examples for implementing different structures of implementations. In order to simplify disclosure of implementations, the components and settings of specific examples are described below. These specific examples are only examples and not for the purpose of limiting the present disclosure. In addition, implementations of the present disclosure may repeat reference numerals and/or reference letters in different examples, and such repetition is for the purpose of simplicity and clarity and does not indicate relationship between various implementations and/or settings discussed. In addition, implementations of the present disclosure provide examples of various specific processes and materials, but those of ordinary skill in the art may be aware of application of other processes and/or use of other materials.

Any process or method description in a flowchart or otherwise described herein may be understood as representing a module, segment, or portion of code that includes one or more executable instructions for implementing specific logical functions or steps of a process. The scope of exemplary implementations includes additional implementations, where the functions may not be performed in the order shown or discussed, including performing functions in a substantially simultaneous manner or in a reverse order according to the functions involved, which shall be understood by those skilled in the art of implementations.

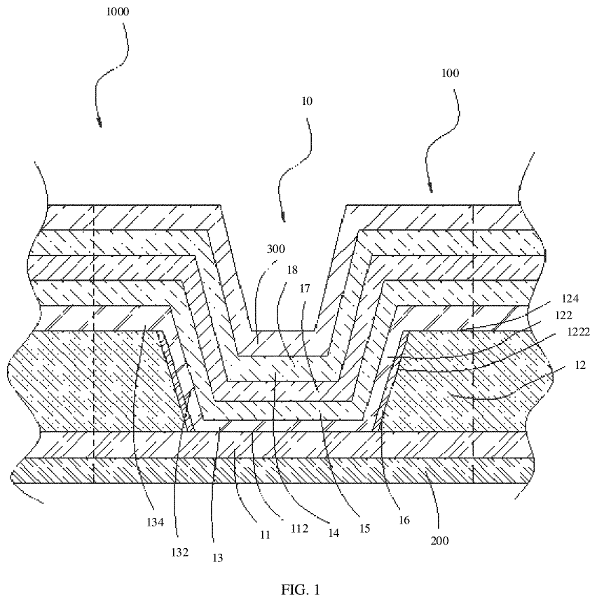

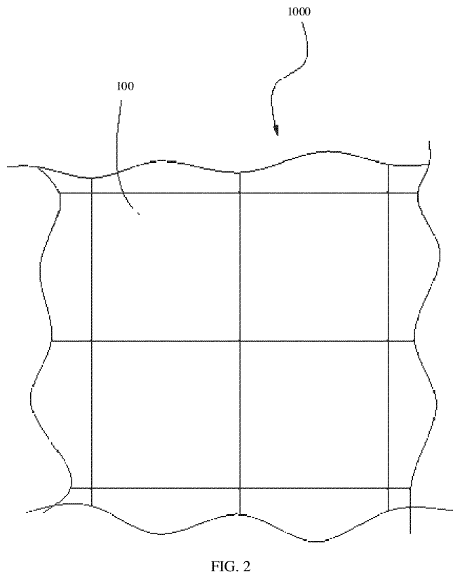

As illustrated in FIG. 1 and FIG. 2, a resonant cavity structure 10 provided herein can be applicable to a pixel 100 of an OLED display panel 1000. The resonant cavity structure 10 includes a PDL 12, a resonant cavity 14, and a reflective film 16. The PDL 12 defines a groove 122 and includes a side surface 1222 of the groove. The resonant cavity 14 is defined in the groove 122. The reflective film 16 is arranged in the groove 122 and covers the side surface 1222 of the groove.

The OLED display panel 1000 includes a TFT substrate 200 and multiple pixels 100 arranged in array on the TFT substrate 200.

According to the resonant cavity structure 10 and the OLED display panel 1000 provided herein, the PDL 12 is covered with the reflective film 16, and as such, light rays directed to the PDL 12 can be reflected back to the resonant cavity 14 for light extraction, which is possible to improve light extraction efficiency.

The OLED display panel 1000 is based on OLED (also called organic electroluminescence display or organic light-emitting semiconductor), which has advantages of self-luminous, wide viewing angle, high contrast, low power consumption, high response speed and so on. The OLED display panel 1000 is enjoying increasing popularity and wider scope of application, for example, the OLED display panel 1000 provided herein can be applied to consumer electronic products such as mobile phones or tablets and has high economic value.

During working, the OLED display panel 1000 can be configured to display a picture, and each pixel 100 can be configured to display picture information, such as color, brightness, etc. of one pixel of the picture.

In some implementations, the PDL 12 is made of photoresist, but the disclosure is not limited thereto. Instead, other proper materials may also be adopted according to actual needs.

Photoresist is also referred to as photosensitive resist and is an organic compound, which is a photosensitive liquid mixture of photosensitive resin, photosensitizer, and solvent. Photosensitive resin, when exposed to light, will be subjected to photocuring reaction which can occur quickly in an exposed area, which makes physical properties (especially solubility and affinity) of photosensitive resin change significantly. After proper solvent treatment, soluble part is dissolved to obtain a desired image. Photoresist is an important material in the micro-manufacturing field and core technology in semiconductor industry. Photoresist is now widely used in processing of fine graphic circuits in optoelectronic information industry, and is an important material for fine processing technology.

In some implementations, the groove 122 has an inverted truncated cone shape and has the side surface 1222 of the groove, and the side surface 1222 of the groove 122 is a bevel which is inclined upwards and outwards.

As such, the groove 122 is in a regular shape, which is convenient for processing and manufacturing. The side surface 1222 of the groove can shorten a transmission distance of light rays within the OLED display panel 1000, which is possible to reduce energy loss of light rays during transmission, thereby improving transmission efficiency.

It should be noted that, the material of the PDL 12 is not limited to the material discussed above. The groove 122 and the side surface 1222 of the groove may be in other proper shapes according to actual needs without being limited to the shape discussed above.

In some implementations, a reflectance of the reflective film 16 to light rays within a predetermined wavelength range is greater than a predetermined value, and a reflectance of the reflective film 16 to light rays beyond the predetermined wavelength range is less than the predetermined value.

In this way, the reflective film 16 can cooperate with the resonant cavity 14 to adjust an emergent light spectrum, such that the OLED display panel 1000 has a prominent display effect. Specifically, for the OLED display panel 1000, in order to achieve a color display effect, an array of color pixels is generally included, for example, in a Bayer pattern. Therefore, each pixel 100 is required to output only a preset color (i.e. the predetermined wavelength range), such as red (R), green (G), or blue (B).

In general, light rays from self-luminous objects have a wide spectrum. However, the resonant cavity 14 can filter for emergent light rays of predetermined wavelengths through a predetermined design (for example, by setting an optical path length of the resonant cavity 14). According to implementations provided herein, the reflective film 16 is introduced for further wavelength adjustment, which can further optimize an emergent light spectrum of the resonant cavity 14, thereby improving a color display effect of the OLED display panel 1000.

In the following, a green pixel 100 of the OLED display panel 1000 is taken as an example to illustrate effect of the reflective film 16 for optimizing an emergent light spectrum.

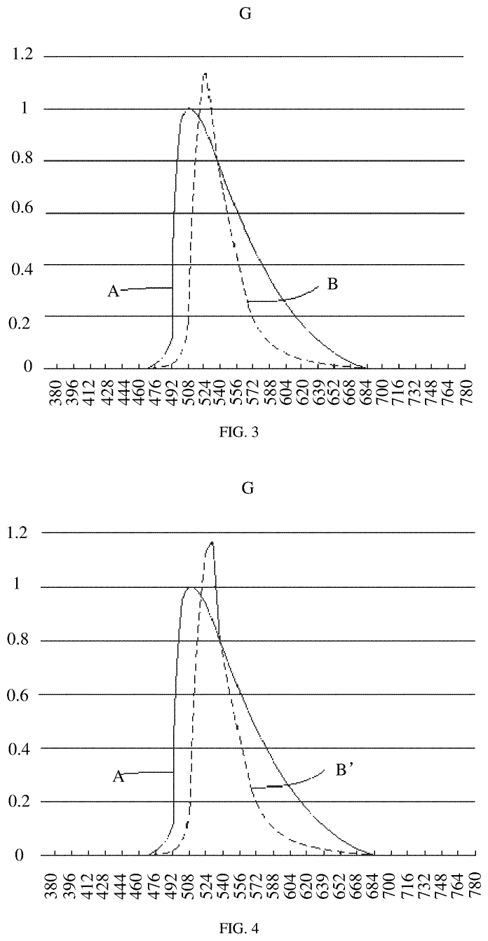

FIG. 3 is a schematic diagram of an emergent light spectrum curve of the resonant cavity structure 10 of the green pixel 100 without the reflective film 16. A horizontal axis represents wavelengths of light rays, and a vertical axis represents light extraction efficiency. Curve A is a spectral curve of light not filtered by the resonant cavity 14 in terms of wavelength, and curve B is a spectral curve of light filtered by the resonant cavity 14 in terms of wavelength. As can be seen, before being filtered by the resonant cavity 14, nearly the entire visible light can exit at a high light extraction efficiency. After passing through the resonant cavity 14, only light of some wavelengths (for example, 524 nm (nanometer)˜540 nm, that is, the predetermined wavelength range) can exit at a high light extraction efficiency (for example, greater than 60%, which is the predetermined value).

FIG. 4 is a schematic diagram of an emergent light spectrum curve of the resonant cavity structure 10 of the green pixel 100 with the reflective film 16. Similarly, a horizontal axis represents wavelengths of light rays, and a vertical axis represents light extraction efficiency. Curve A is a spectral curve of light not filtered by the resonant cavity 14 in terms of wavelength, and curve B′ is a spectral curve of light filtered by the resonant cavity 14 in terms of wavelength. As can be seen, by introducing the reflective film 16, a spectrum can be optimized, and as such, light extraction efficiency of light rays within the predetermined wavelength range can be improved, whereas light extraction efficiency of light rays beyond the predetermined wavelength range can be further reduced.

In the example above, only the green pixel 100 is taken as an example to illustrate effect of the reflective film 16 for optimizing characteristics of an emergent light spectrum. It can be understood that, the same also applies to a red pixel and a blue pixel, which will not be further described herein.

In some implementations, the reflective film 16 includes high refractive index layers and low refractive index layers which are alternately laminated, the high refractive index layer has a refractive index greater than or equal to 1.97, and the low refractive index layer has a refractive index less than or equal to 1.38.

According to experimental evidence, by means of the above structure, an optimal reflection effect can be achieved.

In some implementations, the high refractive index layer has a thickness of 68.52 nm, and the low refractive index layer has a thickness of 97.83 nm.

According to experimental evidence, it is possible to achieve an optimal reflection effect by adopting the thickness above.

In some implementations, the high refractive index layer is made of ZrO2, and the low refractive index layer is made of MgO2.

ZrO2 and MgO2 have high melting point, high resistivity, high refractive index, and low coefficient of thermal expansion. When used as the reflective film 16, ZrO2 and MgO2 have advantages of stable structure and simple process, which can reduce production costs.

In some implementations, the reflective film 16 has nine layers including the high refractive index layers and the low refractive index layers. The high refractive index layers are a first layer, a third layer, a fifth layer, a seventh layer, and a ninth layer, and the low refractive index layers are a second layer, a fourth layer, a sixth layer, and an eighth layer.

Experimental evidence suggests that it is possible to achieve an optimal reflection effect by adopting the thickness above.

As an example, the 9-layer structure, materials, quarter wave optical thicknesses (QWOT), and thicknesses of the reflective film 16 may be such as are illustrated in the table of FIG. 5.

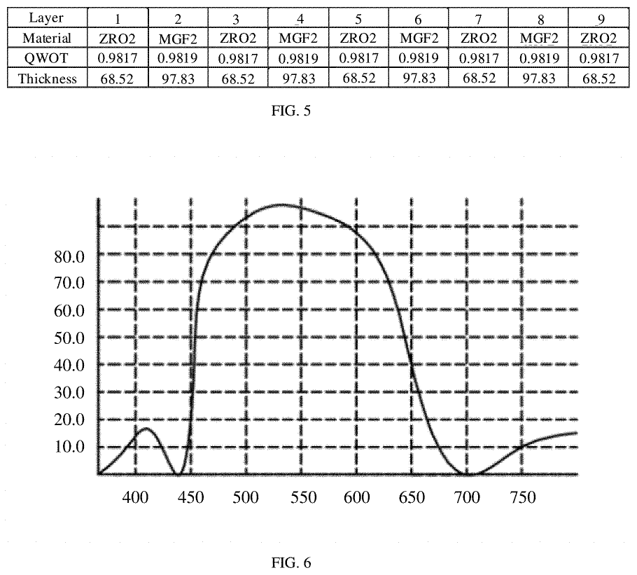

FIG. 6 is a curve diagram of spectral characteristics of the reflective film 16 illustrated in FIG. 5. A horizontal axis represents wavelengths, and a vertical axis represents reflectance. As can be seen, a reflectance of the reflective film to light rays of 450-650 nm is greater than 40%. A peak value of reflectance corresponds to a wavelength falling into 500-550 nm and is greater than 90%. Therefore, the reflective film 16 has optimal spectral characteristics.

It should be noted that, the configuration of the reflective film 16 is not limited to the materials, thicknesses, laminate order, and refractive indexes discussed above. Instead, other proper materials, thicknesses, laminate orders, and refractive indexes may be adopted according to actual needs.

In some implementations, the resonant cavity structure 10 further includes an anode layer 11, a hole layer 13, a light-emitting layer 15, an electron layer 17, and a cathode layer 18. The PDL 12 is arranged on the anode layer 11. The hole layer 13 is arranged on the anode layer 11. The light-emitting layer 15 is arranged on the hole layer 13. The electron layer 17 is arranged on the light-emitting layer 15. The cathode layer 18 is arranged on the electron layer 17. The anode layer 11 and the cathode layer 18 define the resonant cavity 14, in other words, the resonant cavity 14 is defined between the anode layer 11 and the cathode layer 18. A distance between the anode layer 11 and the cathode layer 18 is an optical path length of the resonant cavity 14.

In other words, the OLED display panel 1000 adopts top-emitting OLED display technology. By energizing the anode layer 11 and the cathode layer 18, electrons passing through the electron layer 17 and electron holes passing through the hole layer 13 are combined in the light emitting layer 15 for light emission. Light resonance occurs in the resonance cavity 14, thus achieving better luminous effect.

In some implementations, the anode layer 11 is made of a transparent organic material which has high work function and is at least made of indium tin oxide (ITO).

ITO is a metal compound with excellent transparent and conductive properties and has wide band gap, high light transmittance in the visible region of spectrum, and low resistivity. ITO is widely applied to flat-panel display devices, solar cells, special function window coatings, and other optoelectronic devices.

It should be noted that, the material of the anode layer 11 is not limited to ITO, and the anode layer 11 can also be made of other proper materials according to practical needs.

In some implementations, the hole layer 13 includes a cavity portion 132 and an extension portion 134. The cavity portion 132 is defined in the groove 122 and covers a top surface 112 of the anode layer and the reflective film 16. The extension portion 134 extends from the cavity portion 132 and covers a top surface 124 of the PDL.

The hole layer 13 is configured for hole transport and is usually vulnerable to heat accumulation during working. In addition to high electron-transmission efficiency, the material of the hole layer 13 is required to have high surface stability. Therefore, in some implementations, the hole layer 13 is made of an aromatic amine fluorescent compound and is made of at least one of TPD and TDATA. However, the material of the hole layer 13 is not limited thereto and may be made of other materials according to practical needs.

In some implementations, electrons are combined in the light-emitting layer 15 for light emission. The light-emitting layer 15 is made of the same material as at least one of the electron layer 17 and the hole layer 13. The light-emitting layer 15 and the electron layer may be made of at least one of Alq, Baq, and DPVBi, but the disclosure is not limited in this regard.

Alq is applied for green light, and Baq and DPVBi are applied for blue light. The above materials used for film manufacturing have advantages of high soundness, high thermal stability, and excellent electron-transmission properties, which can improve luminous efficiency, reduce deterioration of components, and thus prolong service life.

In some implementations, the electron layer 17 is made of a fluorescent dye compound. The electron layer 17 may be made of at least one of Alq, Znq, Gaq, Bebq, Balq, DVPBi, ZnSPB, PBD, OXD, and BBOT, but implementations are not limited thereto.

The materials listed above, when in a solid state, have strong fluorescence, excellent carrier transmission properties, high thermal stability and chemical stability, and high quantum efficiency and can be formed through vacuum evaporation (also called vacuum deposition, and hereinafter collectively referred to as vacuum evaporation). On the other hand, these materials are easy to obtain, which can reduce production costs.

In some implementations, the cathode layer 18 is made of metal or alloy which has low work function. For example, the cathode layer 18 may be made of at least one of aluminum (Al), Mg, Ag, and Mg—Ag, but implementations are not limited thereto.

The above materials have low mass, low density, excellent heat dissipation properties, and high compressive strength, which can fully meet requirements of high integration, lightness and thinness, miniaturization, impact resistance, and heat dissipation. On the other hand, these materials have excellent electrical conductivity, which is possible to improve luminous efficiency of components and reduce production costs.

In an example, the anode layer 11, the PDL 12, the reflective film 16, the hole layer 13, the light-emitting layer 15, the electron layer 17, and the cathode layer 18 can be disposed on their respective positions through vacuum evaporation (for example, through vacuum evaporation of thin film and vacuum evaporation of metal electrode).

A multi-layer thin film needs to be vapor-deposited in a high vacuum chamber for the OLED display panel 1000, and the quality of thin film is related to the quality and lifespan of the OLED display panel 1000. Multiple evaporation boats placed with organic materials are provided in the high vacuum chamber. The evaporation boats are heated to evaporate organic materials. Film thickness is controlled with a quartz crystal oscillator. ITO is placed on a heatable rotating sample holder, and a metal mask placed thereunder controls a vapor-deposition pattern. By carrying out a vacuum evaporation experiment on a vacuum evaporation equipment, it can be concluded that an optimal effect of vacuum evaporation can be achieved when an evaporation temperature of an organic material is generally between 170° C. (degrees Celsius) and 400° C., a substrate temperature of ITO sample is between 100° C. and 150° C., an evaporation rate is between 1 crystal oscillation point and 10 crystal oscillation points per second (that is, about 0.1 nm˜1 nm/s), and a vacuum degree of the evaporation chamber is 5×10−4 Pa (Pascal)˜3×10−4 Pa.

Metal electrodes of the OLED display panel 1000 also need to be vapor-deposited in a vacuum chamber. The metal electrodes are usually made of active metals with low work function, and therefore vacuum evaporation is performed on the metal electrodes only after vacuum evaporation performed on a thin film is completed. The metal electrodes are commonly made of Mg/Ag, Mg: Ag/Ag, Li/Al, Lif/Al, etc. Boats used for vacuum evaporation of the metal electrodes are usually made of materials such as Mo, Ta, and W, such that the boats can be used for vacuum evaporation of different metals (mainly to prevent chemical reaction between metal that the boats are made of and metal subjected to vacuum evaporation). Evaporation of metal electrode material is generally expressed by heating current. By carrying out a vacuum evaporation experiment on a vacuum evaporation equipment, it can be concluded that an optimal effect of vacuum evaporation can be achieved when a heating current for evaporation of the metal electrode material is generally between 70 A (ampere) and 100 A (exceptionally, for some metals, the heating current for evaporation is required to exceed 100 A), a substrate temperature of ITO sample is about 80° C., an evaporation rate is 5 crystal oscillator points to 50 crystal oscillator points per second (i.e. about 0.5 nm˜5 nm/s), and a vacuum degree of the evaporation chamber is 7×10−4 pa˜5×10−4 pa.

Vacuum evaporation has a simple process, and each layer of thin film thus obtained has high purity, which can effectively improve the quality of components and working efficiency and reduce production costs.

It should be noted that, the process of each layer is not limited to vacuum evaporation, and other proper processes can be adopted according to actual needs.

In a manufacturing process, the anode layer 11 can be subjected to a pretreatment.

The pretreatment of the anode layer 11 may include the following pretreatment processes. The anode layer 11 which is made of ITO can be taken as an example.

Flatness of an ITO surface can be improved. ITO has been widely used in manufacture of commercial display panels and has advantages of high transmittance, low resistivity, and high work function. In general, ITO manufactured through RF sputtering is susceptible to poor process control factors, which results in an uneven surface and in turn produces sharp substances or protrusions on the surface. In addition, a high temperature calcination and recrystallization process will also produce a protrusion layer of about 10-30 nm on the surface. Paths formed between fine particles of the uneven layer provide an opportunity for electron holes to be directly directed towards a cathode, and these intricate paths increase leakage current. There are generally three methods to reduce effect of such a surface layer. As an example, the thickness of the hole layer can be increased to reduce leakage current. This method is mostly used for polymer light-emitting diodes (LED) and OLEDs with thick hole layers (˜200 nm). As another example, ITO glass is reprocessed to make the surface smooth. As another example, other coating methods are adopted to make the surface smooth.

As another example, work function of ITO can be increased. When electron holes are injected into the light-emitting layer 15 from ITO, an excessive potential difference will generate a Schottky barrier, and as a result, electron holes will be difficult to inject. Therefore, how to reduce the potential difference at an interface between an ITO layer and the light-emitting layer 15 has become a focus of concern in ITO pretreatment. Generally, an O2-Plasma method is adopted to increase the saturation of oxygen atoms in ITO, so as to increase the work function of ITO. The work function of ITO can be increased from the original 4.8 eV (electronvolts) to 5.2 eV after being subjected to O2-Plasma, which is close to work function of the light emitting layer 15.

As another example, an auxiliary electrode can be added. Since the pixel 100 of the OLED display panel 1000 is a current-driven component, when an external circuit is too long or too narrow, a severe voltage gradient will be caused in the external circuit, and as a result, voltage that can be truly applied to the pixel 100 of the OLED display panel 1000 will be decreased, which results in a decrease in light intensity of the panel. Since ITO has a large resistance (10 ohm/square) and thus can easily cause unnecessary external power consumption, as a quick manner to improve luminous efficiency and reduce driving voltage, the voltage gradient can be reduced by adding an auxiliary electrode. Chromium (Cr) is often used as an auxiliary electrode material and has advantages of high stability to environmental factors and wide selection to etchant. However, a resistance value of Cr is 2 ohm/square when a film layer is 100 nm, which is still excessively large in some application scenarios. Therefore, Al which has a lower resistance (0.2 ohm/square) at the same thickness has become an alternative for auxiliary electrode material. However, the high activity of Al also causes a problem of reliability. Therefore, multi-layer auxiliary electrode metals have been proposed, for example, Cr/Al/Cr or Mo/Al/Mo. However, due to complexity and costs of such processes, the choice of auxiliary electrode material has become one of concerns in a process of the OLED display panel 1000.

A treatment process for the cathode layer 18 includes isolation of a fine cathode layer 18 in a high-resolution OLED display panel 1000 mostly in mushroom structure approach, which is similar to negative photoresist development technology of printing technology. During a negative photoresist development process, the quality and yield of the cathode layer 18 will be affected by various process variation factors, such as bulk resistance, dielectric constant, high resolution, high Tg, low critical dimension (CD) loss, and proper adhesion interface with ITO or other organic layers.

The TFT substrate 200 is the first layer of basic structure of the pixels 100 of the whole OLED display panel, which provides a stable structure for the pixels 100 of the OLED display panel.

The TFT substrate 200 has good characteristics in use, low consumption, low driving voltage, high solidification safety, and has various features such as flatness, lightness and thinness, convenience and flexibility in use, easiness in maintenance, update, and upgrade, and long service life.

The OLED display panel 1000 provided herein includes the TFT substrate 200, multiple pixels 100 of the OLED display panel 1000, and a light extraction layer 300. The multiple pixels 100 are arranged in array on the TFT substrate 200. The light extraction layer 300 is arranged on the cathode layer 18.

According to the resonant cavity 14 provided herein, the PDL 12 is covered with the reflective film 16, and as such, light rays directed to the PDL 12 can be reflected back to the resonant cavity 14 for light extraction, which is possible to improve light extraction efficiency.

It can be understood that, in general, the pixels 100 of the OLED display panel 1000 are continuously distributed on the TFT substrate 200 and thus constitutes the OLED display panel 1000. Therefore, the PDL 12 can be continuously distributed on the TFT substrate 200. FIG. 1 merely illustrates part of the OLED display panel 1000.

In the description of the implementations of the present disclosure, it should be understood that the orientation or positional relationship indicated by the terms “upper”, “lower”, “bottom”, “inner”, “outer”, etc. is based on the orientation or positional relationship illustrated in the accompanying drawings, which is merely for the purpose of convenience and simplicity of description of the implementations rather than indicating or implying that the device or element referred to herein must have a specific orientation and be constructed and operated in a specific orientation and therefore cannot be understood as limitations of the disclosure. In addition, the terms “first” and “second” are used for description purposes only, and cannot be understood as indicating or implying relative importance or implicitly indicating the number of technical features indicated. Thus, the features defined as “first” and “second” may explicitly or implicitly include one or more features. In the description of the implementations, the terms“plurality” means two or more, unless otherwise specifically limited.

In the description of the implementations of the present disclosure, it should be noted that, unless otherwise clearly specified and defined, the terms “laminating”, “forming”, “defining”, “reflecting”, etc. should be understood in a broader sense, which may be, for example, all laminated, partially laminated, or indirectly laminated, may be formed or defined physically or chemically, or may be directly reflected or indirectly reflected through an intermediate medium. Those of ordinary skill in the art can understand the specific meanings of the above terms in the implementations according to specific scenarios.

What is claimed is:

1. A resonant cavity structure of a pixel of an organic light emitting diode (OLED) display panel, comprising:
a pixel define layer (PDL) defining a groove and comprising a side surface of the groove;
a resonant cavity defined in the groove; and
a reflective film arranged in the groove and covering the side surface of the groove.

2. The resonant cavity structure of claim 1, wherein the PDL is made of photoresist.

3. The resonant cavity structure of claim 1, wherein the groove has an inverted truncated cone shape, and the side surface of the groove is a bevel which is inclined upwards and outwards.

4. The resonant cavity structure of claim 1, wherein a reflectance of the reflective film to light rays within a predetermined wavelength range is greater than a predetermined value, and a reflectance of the reflective film to light rays beyond the predetermined wavelength range is less than the predetermined value.

5. The resonant cavity structure of claim 4, wherein the reflective film comprises high refractive index layers and low refractive index layers which are alternately laminated, the high refractive index layer has a refractive index greater than or equal to 1.97, and the low refractive index layer has a refractive index less than or equal to 1.38.

6. The resonant cavity structure of claim 5, wherein the high refractive index layer has a thickness of 68.52 nm (nanometer), and the low refractive index layer has a thickness of 97.83 nm.

7. The resonant cavity structure of claim 5, wherein the high refractive index layer is made of ZrO₂, and the low refractive index layer is made of MgO₂.

8. The resonant cavity structure of claim 5, wherein the reflective film 16 has nine layers comprising the high refractive index layers and the low refractive index layers, the high refractive index layers are a first layer, a third layer, a fifth layer, a seventh layer, and a ninth layer, and the low refractive index layers are a second layer, a fourth layer, a sixth layer, and an eighth layer.

9. The resonant cavity structure of claim 1, further comprising:
an anode layer on which the PDL is arranged;
a hole layer arranged on the anode layer;
a light-emitting layer arranged on the hole layer;
an electron layer arranged on the light-emitting layer; and
a cathode layer arranged on the electron layer, wherein
the resonant cavity being defined between the anode layer and the cathode layer, and a distance between the anode layer and the cathode layer is an optical path length of the resonant cavity.

10. The resonant cavity structure of claim 9, wherein the anode layer is made of a transparent organic material which has high work function and is at least made of indium tin oxide (ITO).

11. The resonant cavity structure of claim 9, wherein the hole layer comprises:
a cavity portion defined in the groove and covering a top surface of the anode layer and the reflective film; and
an extension portion extending from the cavity portion and covering the PDL and part of a top surface of the PDL which is in contact with the extension portion.

12. The resonant cavity structure of claim 9, wherein the hole layer is made of an aromatic amine fluorescent compound and is made of at least one of TPD and TDATA.

13. The resonant cavity structure of claim 9, wherein the light-emitting layer is made of the same material as at least one of the electron layer and the hole layer.

14. The resonant cavity structure of claim 9, wherein the light-emitting layer and at least one of the electron layer and the hole layer are made of at least one of Alq, Baq, and DPVBi.

15. The resonant cavity structure of claim 9, wherein the electron layer is made of a fluorescent dye compound.

16. The resonant cavity structure of claim 15, wherein the electron layer is made of at least one of Alq, Znq, Gaq, Bebq, Balq, DVPBi, ZnSPB, PBD, OXD, and BBOT.

17. The resonant cavity structure of claim 9, wherein the cathode layer is made of metal or alloy which has low work function.

18. The resonant cavity structure of claim 17, wherein the cathode layer is made of at least one of aluminum (Al), Mg, Ag, and Mg—Ag.

19. An organic light emitting diode (OLED) display panel, comprising:
a thin-film transistor (TFT) substrate; and
a plurality of pixels arranged in array on the TFT substrate, wherein each of the plurality of pixels comprises a resonant cavity structure, and the resonant cavity structure comprises:
a pixel define layer (PDL) defining a groove and comprising a side surface of the groove;
a resonant cavity defined in the groove; and
a reflective film arranged in the groove and covering the side surface of the groove.

20. The OLED display panel of claim 19, wherein the groove has an inverted truncated cone shape, and the side surface of the groove is a bevel which is inclined upwards and outwards.
